(19) United States
(12) Patent Application Publication
(10) Pub. No.: US 2025/0159764 A1
(43) Pub. Date: May 15, 2025

(54) CERAMIC HEATER

(71) Applicant: NGK INSULATORS, LTD., Nagoya-City (JP)

(72) Inventors: Yutaka UNNO, Handa-Shi (JP); Tomohiro HARA, Handa-Shi (JP)

(73) Assignee: NGK INSULATORS, LTD., Nagoya-City (JP)

(21) Appl. No.: 18/785,110

(22) Filed: Jul. 26, 2024

Related U.S. Application Data
(63) Continuation of application No. PCT/JP2023/040758, filed on Nov. 13, 2023.

(51) Int. Cl. H05B 3/28; H05B 3/06

(52) U.S. Cl. CPC H05B 3/283; H05B 3/06; H05B 2203/005; H05B 2203/037

(57) ABSTRACT

There is provided a ceramic heater including a ceramic plate including a center portion within a radius of 60 mm, an intermediate portion having a radius of 80 to 120 mm, and an outer peripheral portion having a radius of 130 mm or more; and a resistance heating element embedded in the ceramic plate. The resistance heating element is configured such that a volume resistivity of the resistance heating element is gradually increased as a distance from the center is increased. When the volume resistivity of the resistance heating element at an outer edge of the center portion is 100%, a ratio of the volume resistivity of the resistance heating element in the intermediate portion is within a range of 102 to 120%, and a ratio of the volume resistivity of the resistance heating element in the outer peripheral portion is within a range of 108 to 139%.

### CROSS-REFERENCE TO RELATED APPLICATION

This application is a continuation application of PCT/JP2023/040758 filed Nov. 13, 2023, the entire contents of which are incorporated herein by reference.

### BACKGROUND OF THE INVENTION

### 1. Field of the Invention

The present disclosure relates to a ceramic heater.

### 2. Description of the Related Art

In a film formation apparatus for a semiconductor manufacturing process, a ceramic heater is used as a support stage for uniformly controlling a temperature of a wafer. As such a ceramic heater, a ceramic heater including a ceramic plate on which the wafer is to be placed, and a cylindrical ceramic shaft attached to the ceramic plate is widely used. Further, a multi-zone ceramic heater including a plurality of heating zones is also known as the ceramic heater.

Patent Literature 1 (JPH11-339939A) discloses a ceramic heater including a ceramic body embedded with a resistance heating element including a substantially concentric heating pattern or a substantially spiral heating pattern, and a cylindrical supporter that is joined to a lower surface of the ceramic body and is made of ceramic. In the ceramic heater, when an area of a region of the heating pattern positioned inside the cylindrical supporter is denoted by S1, a resistance value of the resistance heating element in the region positioned inside the cylindrical supporter is denoted by R1, an area of a region of the heating pattern positioned outside the cylindrical supporter is denoted by S2, and a resistance value of the resistance heating element in the region positioned outside the cylindrical supporter is denoted by R2, a ratio of R1/S1 is greater than a ratio of R2/S2 within a range of 3% to 60%.

Patent Literature 2 (JPH8-274147A) discloses a wafer holding apparatus in which first to n-th heating resistors (n≥2) sequentially energized are embedded in a ceramic substrate forming a wafer holding surface, and a ratio of a resistance value of an m−1-th heating resistor to a resistance value of an m-th heating resistor (m=2 to n) is set to 1.5 to 4.

Patent Literature 3 (JP2019-194939A) discloses a ceramic heater that includes a disc-shaped ceramic substrate, an electrostatic attraction electrode or a high-frequency generation electrode embedded in the ceramic substrate, a first heating resistor embedded in the ceramic substrate below the electrode, and a second heating resistor embedded in the ceramic substrate below the first heating resistor. The first heating resistor includes a planar first resistive portion provided in an inner region of an imaginary circle defined by an outermost circumferential contour of the electrode, a linear or strip-shaped second resistive portion provided in the inner region at a position outward of the first resistive portion in a radial direction of the ceramic substrate and extending along a circumferential direction of the ceramic substrate, and a connection portion connecting the first resistive portion and the second resistive portion. The second heating resistor is disposed inside an imaginary circle defined by an innermost circumferential contour of the second resistive portion.

Patent Literature 4 (WO2020/153218) discloses a ceramic heater that includes a ceramic plate including an inner-peripheral zone having a circular shape and an outer-peripheral zone having an annular shape, an inner-peripheral resistance heating element that is disposed in the inner-peripheral zone and is made of a high-melting-point metal, and an outer-peripheral resistance heating element disposed in the outer-peripheral zone and having at least a surface made of metal carbide.

### CITATION LIST

### Patent Literature

Patent Literature 1: JPH11-339939A
Patent Literature 2: JPH8-274147A
Patent Literature 3: JP2019-194939A
Patent Literature 4: WO2020/153218

### SUMMARY OF THE INVENTION

Miniaturization and increase in the number of stacked layers for high integration of a semiconductor have been progressing at an accelerated rate, and a temperature and a time of a semiconductor manufacturing process have increased along therewith. As a result, power consumption by a manufacturing apparatus is increasing. On the other hand, responding to SDGs (sustainable development goals) is unavoidable, and it is desirable to increase a voltage of a power supply in order to reduce a power loss in an entire semiconductor manufacturing plant. This is because an increase in voltage of the power supply can reduce a current amount, which makes it possible to reduce the power loss. Further, along with an increase in voltage of the power supply, components constituting the manufacturing apparatus are also required to adapt to the high voltage. In addition, a demand for temperature uniformity (heat uniformity) of the ceramic heater is increasing. Thus, achievement of both adapting the high voltage and the temperature uniformity in the ceramic heater is an urgent issue.

A voltage of a power supply in a semiconductor manufacturing plant has been increased to 208 V so far, but it is anticipated that the voltage will be increased to 440 V or more in the future. As countermeasures against the increase in voltage, a method in which a resistance value of a resistance heating element embedded in the ceramic heater is increased to reduce a current value flowing through the ceramic heater is considered. This is because, when the entire semiconductor manufacturing plant is considered, reduction of the current value in the entire plant enables reduction of the power loss. In the existing ceramic heater, resistance of the resistance heating element has been increased by line thinning and enlargement of a winding diameter in the resistance heating element of a three-dimensional coil type, by line thinning and amplitude expansion in the resistance heating element of a two-dimensional type having a linear zigzag structure, and by reduction in film thickness and in printing width in the resistance heating element of a print pattern type. However, the existing method of increasing the resistance value can increase the resistance, but cannot achieve temperature uniformity of the ceramic heater due to deformation or transformation of the resistance heating element.

The present inventors have found that, in a ceramic heater including a resistance heating element embedded in a center portion, an intermediate portion, and an outer peripheral portion defined in a radial direction from a center of a ceramic plate, it is possible to achieve both reduction in power consumption by increase in resistance and in-plane temperature uniformity of the ceramic plate, by allowing a volume resistivity of the resistance heating element to be gradually increased as a distance from the center of the ceramic plate is increased, and adjusting ratios of the volume resistivities of the resistance heating element in the intermediate portion and the outer peripheral portion to the volume resistivity of the resistance heating element at an outer edge of the center portion within respective predetermined ranges.

Therefore, an object of the present invention is to provide a ceramic heater that can achieve both reduction in power consumption by increase in resistance and in-plane temperature uniformity of a ceramic plate.

The present disclosure provides the following aspects.

### [Aspect 1]

A ceramic heater, comprising:
a ceramic plate having a disc shape, including a first surface on which a wafer is to be placed and a second surface opposite to the first surface, and including, in a planar view, a center portion defined as a circular region within a radius of 60 mm from a center of the ceramic plate, an intermediate portion defined as an annular region having a radius of 80 mm to 120 mm from the center, and an outer peripheral portion defined as an annular region having a radius of 130 mm or more from the center; and
a resistance heating element embedded in the center portion, the intermediate portion, and the outer peripheral portion in the ceramic plate, wherein
the resistance heating element is configured such that a volume resistivity of the resistance heating element is gradually increased as a distance from the center of the ceramic plate is increased, and
when the volume resistivity of the resistance heating element at an outer edge of the center portion is 100%, a ratio of the volume resistivity of the resistance heating element in the intermediate portion is within a range of 102% to 120%, and a ratio of the volume resistivity of the resistance heating element in the outer peripheral portion is within a range of 108% to 139%.

### [Aspect 2]

The ceramic heater according to aspect 1, wherein the resistance heating element has at least one form selected from a group consisting of a coil, a linear zigzag structure, a print pattern, a foil, and a mesh.

### [Aspect 3]

The ceramic heater according to aspect 1 or 2, wherein
a part of the resistance heating element embedded in the center portion, a part of the resistance heating element embedded in the intermediate portion, and a part of the resistance heating element embedded in the outer peripheral portion are each disposed in a one-stroke form in a planar view, and
the part of the resistance heating element embedded in the center portion, the part of the resistance heating element embedded in the intermediate portion, and the part of the resistance heating element embedded in the outer peripheral portion are made of a same material.

### [Aspect 4]

The ceramic heater according to aspect 3, wherein
the ceramic heater includes at least two resistance heating elements,
one of the resistance heating elements embedded in the center portion, the intermediate portion, and the outer peripheral portion forms, as one continuous resistance heating element, an outer zone control heater circuit, and
another of the resistance heating elements embedded at a depth position different from a depth position of the outer zone control heater circuit in the center portion, the intermediate portion, and the outer peripheral portion forms, as one continuous resistance heating element, an inner zone control heater circuit independent of the outer zone control heater circuit.

### [Aspect 5]

The ceramic heater according to aspect 3, wherein
the ceramic heater includes at least two resistance heating elements,
the resistance heating element embedded in the outer peripheral portion or in the outer peripheral portion and the intermediate portion forms, as one continuous resistance heating element, an outer zone control heater circuit, and
the resistance heating element embedded in the center portion or in the center portion and the intermediate portion forms, as one continuous resistance heating element, an inner zone control heater circuit independent of the outer zone control heater circuit.

### [Aspect 6]

The ceramic heater according to any one of aspects 1 to 5, wherein the ceramic plate contains aluminum nitride or aluminum oxide.

### [Aspect 7]

The ceramic heater according to aspect 6, wherein the ceramic plate contains aluminum nitride and includes an upper ceramic plate providing the first surface and a lower ceramic plate providing the second surface, and aluminum nitride constituting the upper ceramic plate has a volume resistivity exceeding 1.0×10⁸ Ω·cm at 550° C.

### [Aspect 8]

The ceramic heater according to any one of aspects 1 to 7, further comprising an inner electrode as an RF electrode and/or an ESC electrode in the ceramic plate.

### [Aspect 9]

The ceramic heater according to any one of aspects 1 to 8, further comprising a cylindrical ceramic shaft that is concentrically attached to the second surface of the ceramic plate and includes an internal space.

### BRIEF DESCRIPTION OF THE DRAWINGS

FIG. 1 is a top view schematically illustrating an example of a ceramic heater according to the present invention.

FIG. 2 is a perspective cross-sectional view schematically illustrating a cross-sectional structure of the ceramic heater illustrated in FIG. 1.

FIG. 3 is a top view schematically illustrating another example of the ceramic heater according to the present invention.

FIG. 4 is a perspective cross-sectional view schematically illustrating a cross-sectional structure of the ceramic heater illustrated in FIG. 3. Note that, for convenience of description, to facilitate understanding of configurations of an inner zone control heater circuit 14a and jumpers 22 that are originally positioned at the same height, the jumpers 22 are drawn at a position slightly lower than the original position.

FIG. 5 is a schematic diagram conceptually illustrating a pattern and heat generation density of the inner zone control heater circuit adopted in Examples 1 to 5. In the drawing, a thickness of a line indicates the heat generation density.

FIG. 6 is a schematic diagram conceptually illustrating a pattern and heat generation density of an outer zone control heater circuit adopted in Examples 1 to 5. In the drawing, a thickness of a line indicates the heat generation density.

FIG. 7 is a graph illustrating distribution of volume resistivity ratios relative to a radial-direction position of a heating resistor measured in Examples 1 to 5.

### DETAILED DESCRIPTION OF THE INVENTION

A ceramic heater according to the present invention is a stand made of ceramic for supporting a wafer inside a semiconductor manufacturing apparatus. The ceramic heater according to the present invention may be typically a ceramic heater for a semiconductor film formation apparatus. Typical examples of the film formation apparatus include a CVD (chemical vapor deposition) apparatus (for example, thermal CVD apparatus, plasma CVD apparatus, optical CVD apparatus, and MOCVD apparatus), and a PVD (physical vapor deposition) apparatus.

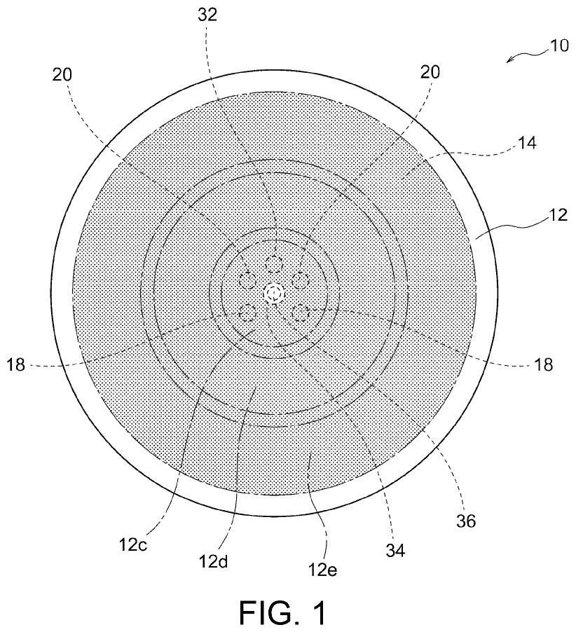

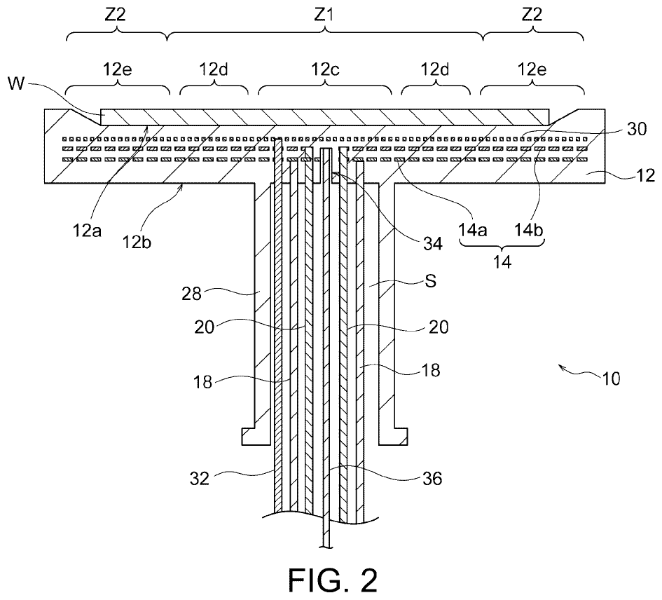

FIGS. 1 and 2 illustrate an example of a two-zone ceramic heater as one aspect of the ceramic heater. A ceramic heater 10 illustrated in FIGS. 1 and 2 includes a ceramic plate 12 and a resistance heating element 14. The ceramic plate 12 has a disc shape, and includes a first surface 12a on which a wafer W is to be placed, and a second surface 12b opposite to the first surface 12a. In a planar view of the ceramic plate 12, the ceramic plate 12 includes a center portion 12c, an intermediate portion 12d, and an outer peripheral portion 12e. The center portion 12c is defined as a circular region within a radius of 60 mm from a center of the ceramic plate 12. The intermediate portion 12d is defined as an annular region having a radius of 80 mm to 120 mm from the center of the ceramic plate 12. The outer peripheral portion 12e is defined as an annular region having a radius of 130 mm or more from the center of the ceramic plate 12. The resistance heating element 14 is embedded in the center portion 12c, the intermediate portion 12d, and the outer peripheral portion 12e in the ceramic plate 12. The resistance heating element 14 is configured such that a volume resistivity of the resistance heating element 14 is gradually increased as a distance from the center of the ceramic plate 12 is increased. When the volume resistivity of the resistance heating element 14 at an outer edge of the center portion 12c is 100%, a ratio of the volume resistivity of the resistance heating element 14 in the intermediate portion 12d is within a range of 102% to 120%, and a ratio of the volume resistivity of the resistance heating element 14 in the outer peripheral portion 12e is within a range of 108% to 139%. As described above, in the ceramic heater 10 including the resistance heating element 14 embedded in the center portion 12c, the intermediate portion 12d, and the outer peripheral portion 12e defined in the radial direction from the center of the ceramic plate 12, the volume resistivity of the resistance heating element 14 is made so as to be gradually increased as the distance from the center of the ceramic plate 12 is increased, and the ratios of the volume resistivities of the resistance heating element 14 in the intermediate portion 12d and the outer peripheral portion 12e to the volume resistivity of the resistance heating element 14 at the outer edge of the center portion 12c are adjusted within the respective predetermined ranges, which makes it possible to achieve both reduction in power consumption by an increase in resistance and in-plane temperature uniformity of the ceramic plate 12.

As described above, achievement of both adapting the high voltage and the temperature uniformity in the ceramic heater is an urgent issue. For example, a voltage of a power supply in a semiconductor manufacturing plant has been increased to 208 V so far, but it is anticipated that the voltage will be increased to 440 V or more in the future. As countermeasures against the increase in voltage, a method in which a resistance value of a resistance heating element embedded in the ceramic heater is increased to reduce a current value flowing through the ceramic heater is considered. In the existing ceramic heater, resistance of the resistance heating element has been increased by line thinning and enlargement of a winding diameter in the resistance heating element of a three-dimensional coil type, by line thinning and amplitude expansion in the resistance heating element of a two-dimensional type having a linear zigzag structure, and by reduction in film thickness and in printing width in the resistance heating element of a print pattern type. However, in the resistance heating element of the three-dimensional coil type, the resistance value is doubled by line thinning and enlargement of the winding diameter, but the temperature uniformity becomes more difficult because a coil shape and a pattern are easily deformed during manufacture. In the resistance heating element of the two-dimensional type having the linear zigzag structure, the resistance value is doubled by line thinning and amplitude expansion, but the temperature uniformity is deteriorated due to deformation during manufacture as described above. In the resistance heating element of the print pattern type, the resistance value is doubled by reduction in film thickness and in printing width, but transformation of the resistance heating element easily occurs during manufacture, and the temperature uniformity becomes more difficult as described above. As described above, the existing method of increasing the resistance value can increase the resistance, but cannot achieve temperature uniformity of the ceramic heater due to deformation or transformation of the resistance heating element.

Therefore, a firing method during manufacture of the ceramic plate 12 was revised, and a series of firing processes from temperature rise to temperature drop through the highest temperature was largely changed. As a result, deformation of the resistance heating element 14 could be suppressed, and the volume resistivity of the entire resistance heating element 14 could be increased with a desired profile. The temperature uniformity was improved by these attempts. Accordingly, the volume resistivity of the resistance heating element 14 could be relatively increased so as to be gradually increased as the distance from the center of the ceramic plate 12 is increased (i.e. toward outer periphery). This made it possible to largely increase the resistance value of the resistance heating element 14 as compared with the existing technique, and the resistance value of the resistance heating element 14 disposed in a region close to the outer periphery was relatively higher than the resistance value of the resistance heating element 14 disposed in a region close to the center of the ceramic plate 12. As a result, in terms of the apparatus configuration and the process condition, reduction of the current value that often largely flowed in the region close to the outer periphery of the ceramic plate 12 was achieved. Accordingly, both reduction of the current value (leading to reduction in power consumption) by increase in resistance and the in-plane temperature uniformity of the ceramic plate 12 could be improved. Note that, an increase in volume resistivity of the entire resistance heating element 14 was more effective because of reduction of the current value. However, to increase the volume resistivity of the entire resistance heating element 14, a firing time is doubled, and power consumption in firing is also doubled, which is preposterous. Further, deformation of the resistance heating element may be increased with doubling of the firing time. Thus, it was concluded that a method in which the volume resistivity of the resistance heating element 14 disposed in the region close to the outer periphery was made higher than the volume resistivity of the resistance heating element 14 disposed in the region close to the center of the ceramic plate was optimum to achieve both reduction in power consumption and temperature uniformity, and the present invention was made.

In terms of excellent heat conductivity, high electric insulation property, thermal expansion characteristics close to silicon, and the like, a main portion (namely, ceramic substrate) of the ceramic plate 12 other than embedded members such as the resistance heating element 14 preferably contains aluminum nitride or aluminum oxide, and more preferably contains aluminum nitride. In a preferred aspect, the ceramic plate 12 contains aluminum nitride, and includes an upper ceramic plate providing the first surface 12a and a lower ceramic plate providing the second surface 12b. In the aspect, the aluminum nitride constituting the upper ceramic plate preferably has a volume resistivity exceeding 1.0×10⁸ Ω·cm at 550° C., and more preferably has a volume resistivity of 1.0×10⁹ Ω·cm to 1.0×10¹¹ Ω·cm.

The ceramic plate 12 has a disc shape. However, the ceramic plate 12 formed in the disc shape is not required to have a complete circular shape in a planar view, and the ceramic plate 12 may have an incomplete circular shape partially cut away, such as an orientation flat in a planar view. A diameter of the ceramic plate 12 is typically 320 mm to 380 mm for a 300 mm silicon wafer, and is, for example, about 340 mm. A thickness of the ceramic plate 12 is typically 10 mm to 25 mm, and is, for example, about 20 mm.

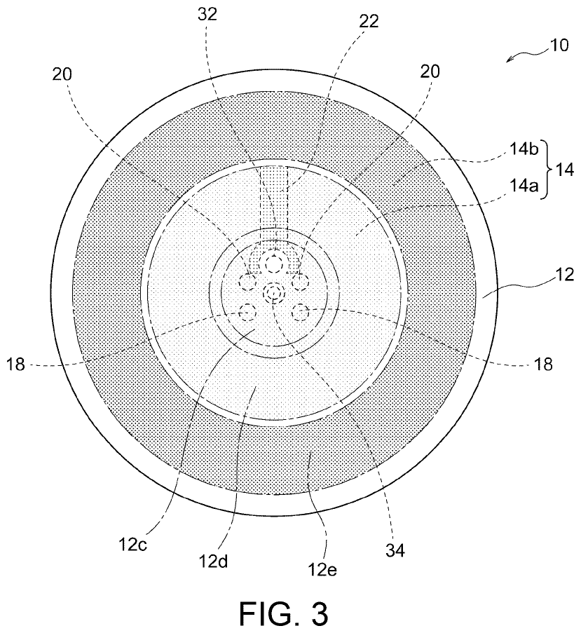

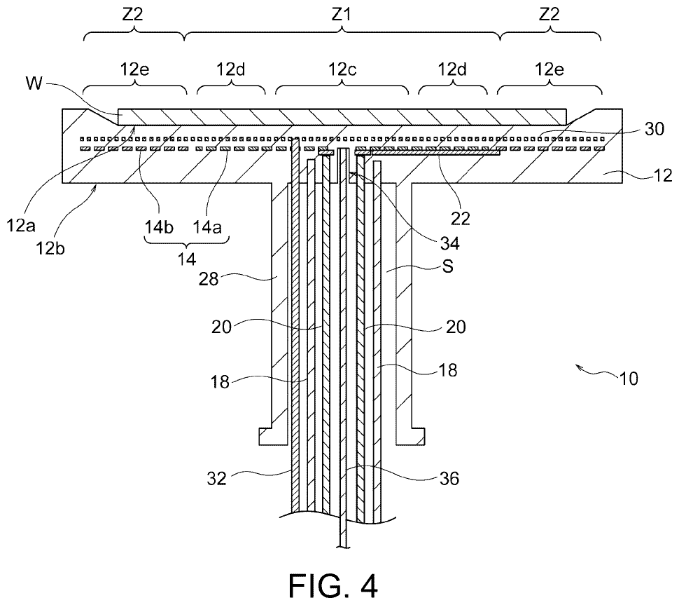

The resistance heating element 14 is embedded in the center portion 12c, the intermediate portion 12d, and the outer peripheral portion 12e in the ceramic plate 12. As described above, the center portion 12c is defined as a circular region within a radius of 60 mm from the center of the ceramic plate 12. The intermediate portion 12d is defined as an annular region having a radius of 80 mm to 120 mm from the center of the ceramic plate 12. The outer peripheral portion 12e is defined as an annular region having a radius of 130 mm or more from the center of the ceramic plate 12. Accordingly, an annular region having a width of 20 mm is present between the center portion 12c and the intermediate portion 12d, and an annular region having a width of 10 mm is present between the intermediate portion 12d and the outer peripheral portion 12e. These annular regions not belonging to any of the center portion 12c, the intermediate portion 12d, and the outer peripheral portion 12e are merely excluded from calculation of the ratio of the volume resistivity of the resistance heating element 14, and the resistance heating element 14 may be present in these annular regions. In other words, as illustrated in FIGS. 1 and 2, the resistance heating element 14 may be continuously embedded over the center portion 12c, the intermediate portion 12d, and the outer peripheral portion 12e (including annular regions among these portions) in the ceramic plate 12. Alternatively, as illustrated in FIGS. 3 and 4, the resistance heating element 14 may be a combination of a resistance heating element 14 (inner zone control heater circuit 14a) continuously embedded over the center portion 12c and the intermediate portion 12d (including annular region therebetween) in the ceramic plate 12 and another resistance heating element 14 (outer zone control heater circuit 14b) embedded in the outer peripheral portion 12e in the ceramic plate 12.

The resistance heating element 14 is configured such that the volume resistivity of the resistance heating element 14 is gradually increased as the distance from the center of the ceramic plate 12 is increased. More specifically, when the volume resistivity of the resistance heating element 14 at the outer edge of the center portion 12c is 100%, the ratio of the volume resistivity of the resistance heating element 14 in the intermediate portion 12d is within a range of 102% to 120%, preferably within a range of 103% to 118%, and more preferably within a range of 105% to 115%. The ratio of the volume resistivity of the resistance heating element 14 in the outer peripheral portion 12e is within a range of 108% to 139%, preferably within a range of 112% to 135%, and more preferably within a range of 116% to 130%. When the ratios are within these ranges, reduction in power consumption by increase in resistance and the in-plane temperature uniformity of the ceramic plate 12 can be more effectively achieved.

The resistance heating element 14 preferably has at least one form selected from a group consisting of a coil, a linear zigzag structure, a print pattern, a foil, and a mesh.

A part of the resistance heating element 14 embedded in the center portion 12c, a part of the resistance heating element 14 embedded in the intermediate portion 12d, and a part of the resistance heating element 14 embedded in the outer peripheral portion 12e are each preferably disposed in a one-stroke form in a planar view. The one-stroke form may be any of various well-known forms such as a spiral shape. The part of the resistance heating element 14 embedded in the center portion 12c, the part of the resistance heating element 14 embedded in the intermediate portion 12d, and/or the part of the resistance heating element 14 embedded in the outer peripheral portion 12e may be continuous with one another or separated from one another. Therefore, the resistance heating element 14 may be a one-zone heater circuit continuously disposed over the center portion 12c, the intermediate portion 12d, and the outer peripheral portion 12e, or a multi-zone heater circuit divided into two or more zones. For example, as illustrated in FIGS. 1 and 2, the resistance heating element 14 may be continuously disposed in a one-stroke form over the center portion 12c, the intermediate portion 12d, and the outer peripheral portion 12e. Alternatively, as illustrated in FIGS. 3 and 4, a part of the resistance heating element 14 may be disposed in a one-stroke form in an inner zone Z1 to form the inner zone control heater circuit 14a, and the other part may be disposed in a one-stroke form in an outer zone Z2 to form the outer zone control heater circuit 14b. In any case, in the ceramic heater 10, the part of the resistance heating element 14 embedded in the center portion 12c, the part of the resistance heating element 14 embedded in the intermediate portion 12d, and the part of the resistance heating element 14 embedded in the outer peripheral portion 12e are preferably made of the same material. This is because the firing method during manufacture of the ceramic plate 12 is revised, and accordingly, the resistance and the volume resistivity can be desirably controlled even in the resistance heating element 14 entirely made of the same material. In that sense, even when the same material is used, the volume resistivity varies depending on the positions of the center portion 12c, the intermediate portion 12d, the outer peripheral portion 12e, and the like by firing (for example, due to carbonization degree). Therefore, the “same material” used herein means that an original material before firing is the same without considering transformation (for example, carbonization) or change in volume resistivity caused by firing (in that sense, may also be referred to as “essentially same material”).

As described above, in a planar view, the ceramic plate 12 may include the inner zone Z1 and the outer zone Z2. The inner zone Z1 is defined as a circular region within a predetermined distance from the center of the ceramic plate 12, and typically includes the center portion 12c and a part or all of the intermediate portion 12d optionally. The outer zone Z2 is defined as an annular region outside the inner zone Z1, and typically includes the outer peripheral portion 12e and a part or all of the intermediate portion 12d optionally. Therefore, the inner zone Z1 and the center portion 12c (or combined region of center portion 12c and intermediate portion 12d) are not always coincident with each other, and the outer zone Z2 and the outer peripheral portion 12e (or combined region of outer peripheral portion 12e and intermediate portion 12d) are not always coincident with each other. The outer zone Z2 may include a plurality of outer sub-zones each sectioned in an arc shape. The outer zone Z2 may concentrically include two or more annular regions that have different sizes and do not overlap with each other. In this case, the outer zone Z2 at least include a first outer zone close to the inner zone Z1 and a second outer zone positioned outside the first outer zone. As necessary, third or further outer zones may be present outside the second outer zone.

In a preferred aspect of the present invention, as illustrated in FIGS. 1 and 2, the ceramic heater 10 may include at least two resistance heating elements 14 in overlapping regions. In the aspect, one of the resistance heating elements 14 embedded in the center portion 12c, the intermediate portion 12d, and the outer peripheral portion 12e preferably forms, as one continuous resistance heating element, the outer zone control heater circuit 14b for selectively or preferentially heating the outer zone Z2, and the other of the resistance heating elements 14 embedded at a depth position different from a depth position of the outer zone control heater circuit 14b in the center portion 12c, the intermediate portion 12d, and the outer peripheral portion 12e preferably forms, as one continuous resistance heating element, the inner zone control heater circuit 14a for selectively or preferentially heating the inner zone Z1, independent of the outer zone control heater circuit 14b. In the aspect, although the inner zone control heater circuit 14a and the outer zone control heater circuit 14b are disposed at the different depth positions in the overlapping regions each including the center portion 12c, the intermediate portion 12d, and the outer peripheral portion 12e, the inner zone control heater circuit 14a is configured to selectively perform heating in the inner zone Z1 by being disposed such that the resistance is high in the inner zone Z1 and the resistance is low in the outer zone Z2 (for example, in case of coil, by changing coil pitch). Likewise, the outer zone control heater circuit 14b is configured to selectively perform heating in the outer zone Z2 by being disposed such that the resistance is low in the inner zone Z1 and the resistance is high in the outer zone Z2 (for example, in case of coil, by changing coil pitch).

In another preferred aspect of the present invention, as illustrated in FIGS. 3 and 4, the ceramic heater 10 includes at least two resistance heating elements 14 in different regions. In the aspect, the resistance heating element 14 embedded in the outer zone Z2 (typically, outer peripheral portion 12e, or outer peripheral portion 12e and intermediate portion 12d) preferably forms, as one continuous resistance heating element 14, the outer zone control heater circuit 14b for selectively or preferentially heating the outer zone Z2, and the resistance heating element embedded in the inner zone Z1 (typically, center portion 12c, or center portion 12c and intermediate portion 12d) preferably forms, as one continuous resistance heating element 14, the inner zone control heater circuit 14a for selectively or preferentially heating the inner zone Z1, independent of the outer zone control heater circuit 14b.

In any aspects illustrated in FIGS. 1 to 4, the inner zone control heater circuit 14a is embedded in parallel with the first surface 12a in the inner zone Z1 (and outer zone Z2 if present) of the ceramic plate 12. A pair of first power supply terminals 18 for supplying power to the inner zone control heater circuit 14a is provided at a center part of the inner zone Z1 of the ceramic plate 12. Preferably, the first power supply terminals 18 are connected to respective ends of the inner zone control heater circuit 14a. Two or more pairs of first power supply terminals 18 may be provided. Each of the first power supply terminals 18 has a rod shape, and the inner zone control heater circuit 14a is connected to a heater power supply (not illustrated) through the first power supply terminals 18 each having the rod shape.

In any aspects illustrated in FIGS. 1 to 4, the outer zone control heater circuit 14b is embedded in parallel with the first surface 12a in the outer zone Z2 (and inner zone Z1 if present) of the ceramic plate 12. A pair of second power supply terminals 20 for supplying power to the outer zone control heater circuit 14b is provided at the center part (but different from positions of first power supply terminals 18) of the inner zone Z1 of the ceramic plate 12. The pair of second power supply terminals 20 may be directly connected to the outer zone control heater circuit 14b as illustrated in FIG. 2, or may be electrically connected to the outer zone control heater circuit 14b through a pair of jumpers 22 as illustrated in FIG. 4. Two or more pairs of second power supply terminals 20 may be provided. Each of the second power supply terminals 20 has a rod shape, and the outer zone control heater circuit 14b is connected to a heater power supply (not illustrated) through the second power supply terminals 20 each having the rod shape (through jumpers 22 as necessary).

The ceramic plate 12 may further include an RF electrode 30 and/or an ESC electrode as an internal electrode. In this case, the RF electrode 30 and/or the ESC electrode is preferably embedded at a depth position closer to the first surface 12a as compared with the resistance heating element 14 (and jumpers 22 if present) of the ceramic plate 12. The RF electrode enables film formation by a plasma CVD process by receiving a radio frequency. The ESC electrode is an abbreviation for an electrostatic chuck (ESC) electrode, and is also referred to as an electrostatic electrode. When a voltage is applied from an external power supply to the ESC electrode, the ESC electrode chucks a wafer placed on a surface of the ceramic plate 12 with Johnson Rahbeck force. The ESC electrode is preferably a circular thin layer electrode having a diameter slightly smaller than the diameter of the ceramic plate 12, and may be, for example, a mesh-shaped electrode obtained by knitting thin metal wires to a mesh sheet. The ESC electrode may be used as a plasma electrode. In other words, when the radio frequency is applied to the ESC electrode, the ESC electrode can be used as the RF electrode, which enables film formation by a plasma CVD process. An RF terminal 32 or an ESC terminal for supplying power is connected to the RF electrode 30 or the ESC electrode. The RF terminal 32 or the ESC terminal has a rod shape, and the RF electrode 30 or the ESC electrode is connected to an external power supply (not illustrated) through the RF terminal 32 or the ESC terminal having the rod shape.

Optionally, a ceramic shaft 28 may be concentrically attached to the second surface 12b of the ceramic plate 12. The ceramic shaft 28 is a cylindrical member including an internal space S, and may have a configuration similar to a configuration of a ceramic shaft adopted in a well-known ceramic susceptor or ceramic heater. The internal space S is configured to allow terminal rods such as the first power supply terminals 18, the second power supply terminals 20, and the RF terminal 32 to pass therethrough. The ceramic shaft 28 is preferably made of a ceramic material as with the ceramic plate 12. Accordingly, the ceramic shaft 28 preferably contains aluminum nitride or aluminum oxide, and more preferably contains aluminum nitride. An upper end surface of the ceramic shaft 28 is preferably joined to the second surface 12b of the ceramic plate 12 by solid-phase joining or diffusion joining. An outer diameter of the ceramic shaft 28 is preferably 40 mm to 60 mm, and is, for example, about 55 mm. An inner diameter of the ceramic shaft 28 (diameter of internal space S) is preferably 33 mm to 55 mm, and is, for example, about 50 mm.

The ceramic plate 12 may include a thermocouple insertion hole 34. The thermocouple insertion hole 34 may be a vertical hole formed from the second surface 12b toward the first surface 12a. When a thermocouple 36 is inserted into the thermocouple insertion hole 34, a temperature of the ceramic plate 12 to the internal electrode such as the RF electrode 30 can be measured. In this case, the thermocouple insertion hole 34 preferably reaches the internal electrode such as the RF electrode 30 or a vicinity thereof.

The ceramic plate 12 having a specific volume resistivity ratio profile according to the present invention can be preferably manufactured in the following manner, for example. First, aluminum nitride powder is press-molded to obtain a first aluminum nitride green compact. Aluminum nitride powder and the inner zone control heater circuit 14a are disposed on the obtained first aluminum nitride green compact, followed by press molding, to obtain a second aluminum nitride green compact in which the inner zone control heater circuit 14a is embedded. Aluminum nitride powder and the outer zone control heater circuit 14b are disposed on the obtained second aluminum nitride green compact, followed by press molding, to obtain a third aluminum nitride green compact in which the outer zone control heater circuit 14b is further embedded. Aluminum nitride powder and the RF electrode 30 are disposed on the obtained third aluminum nitride green compact, followed by press molding, to obtain a fourth aluminum nitride green compact in which the RF electrode 30 is further embedded. In the above-described manner, a press-molded body composed of the aluminum nitride green compact in which the inner zone control heater circuit 14a, the outer zone control heater circuit 14b, and the RF electrode 30 are embedded as illustrated in FIG. 2 is obtained. These processes are similar to the existing technique, and can be performed by a well-known manufacturing method. To obtain the ceramic plate 12 according to the present invention, the obtained press-molded body (stacked body) is preferably fired under the following specific firing condition in a nitrogen atmosphere.
Highest temperature: 1760° C. to 1870° C.
Holding time at highest temperature: 5 hours to 13 hours
Number of times of changing temperature rise rate before highest temperature: 2 times to 7 times
Temperature rise rate: changed within a range of 40° C./minute to 60° C./minute
Firing pressure: 60 kg/cm² to 120 kg/cm²

Performing such firing makes it possible to change a carbonization degree of the resistance heating element 14 based on a position in the radial direction. This makes it possible to realize the volume resistivity of the desired profile based on the positions of the center portion 12c, the intermediate portion 12d, the outer peripheral portion 12e, and the like in the radial direction.

### EXAMPLES

The present invention is more specifically described using the following examples. However, the present invention is not limited to the following examples.

### Examples 1 to 5

### (1) Fabrication of Two-Zone Ceramic Heater

The two-zone ceramic heater 10 having the structure illustrated in FIGS. 1 and 2 was fabricated using the following configuration members by a well-known procedure except for the firing condition.

### <Configuration Member and Specification>

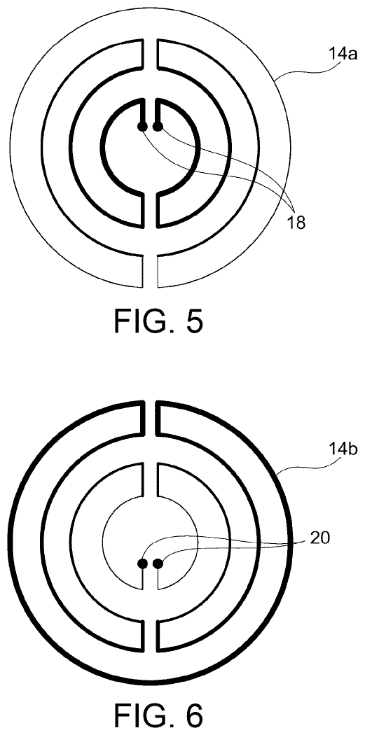

Ceramic plate 12: disc-shaped aluminum nitride sintered body (diameter: 330 mm, thickness: 20 mm, volume resistivity at 550° C.: 1.0×10¹⁰ Ω·cm (coupon (specimen) was cut out and measured at 550° C.)) (inner zone control heater circuit 14a, outer zone control heater circuit 14b, and RF electrode 30 were internally embedded)
Ceramic shaft 28: cylindrical aluminum nitride sintered body (height: 170 mm, outer diameter: 45 mm, inner diameter: 36 mm)
Inner zone control heater circuit 14a: coil embedded based on circuit pattern illustrated in FIG. 5, at depth position of 11.5 mm from first surface 12a in inner zone Z1 and outer zone Z2 (region having diameter of 320 mm) of ceramic plate 12 (material: molybdenum, line diameter: 500 μm, outer diameter: 3.5 mm, disposed such that coil pitch is reduced (coil becomes dense) toward center of ceramic plate 12 as conceptually illustrated by thickness of line in circuit pattern of FIG. 5)
Outer zone control heater circuit 14b: coil embedded based on circuit pattern illustrated in FIG. 6, at depth position of 6.5 mm from first surface 12a in inner zone Z1 and outer zone Z2 (region having diameter of 320 mm) of ceramic plate 12 (material: molybdenum, line diameter: 500 μm, outer diameter: 3.5 mm, disposed such that coil pitch is reduced (coil becomes dense) toward outer periphery of ceramic plate 12 as conceptually illustrated by thickness of line in circuit pattern of FIG. 6)
RF electrode 30: electrode made of molybdenum, embedded at depth position of 1.0 mm from first surface 12a of ceramic plate 12
First power supply terminals 18: two terminal rods made of nickel
Second power supply terminals 20: two terminal rods made of nickel
RF terminal 32: one terminal rod made of nickel

The above-described ceramic plate 12 in which the inner zone control heater circuit 14a, the outer zone control heater circuit 14b, and the RF electrode 30 were embedded was fabricated by the following procedure. First, aluminum nitride powder was press-molded to obtain a first aluminum nitride green compact. Aluminum nitride powder and the inner zone control heater circuit 14a were disposed on the obtained first aluminum nitride green compact, followed by press molding, to obtain a second aluminum nitride green compact in which the inner zone control heater circuit 14a having the pattern illustrated in FIG. 5 was embedded. Aluminum nitride powder and the outer zone control heater circuit 14b were disposed on the obtained second aluminum nitride green compact, followed by press molding, to obtain a third aluminum nitride green compact in which the outer zone control heater circuit 14b having the pattern illustrated in FIG. 6 was further embedded. Aluminum nitride powder and the RF electrode 30 were disposed on the obtained third aluminum nitride green compact, followed by press molding, to obtain a fourth aluminum nitride green compact in which the RF electrode 30 was further embedded. In the above-described manner, a press-molded body composed of the aluminum nitride green compact in which the inner zone control heater circuit 14a, the outer zone control heater circuit 14b, and the RF electrode 30 were embedded as illustrated in FIG. 2 was obtained. The obtained press-molded body (stacked body) was fired under a firing condition illustrated in Table 1 in a nitrogen atmosphere, to obtain the ceramic plate 12 in which the inner zone control heater circuit 14a, the outer zone control heater circuit 14b, and the RF electrode 30 were embedded.

### (2) Evaluation

Various kinds of evaluations were performed on the obtained two-zone ceramic heater.

### <Distribution of Volume Resistivity Ratio>

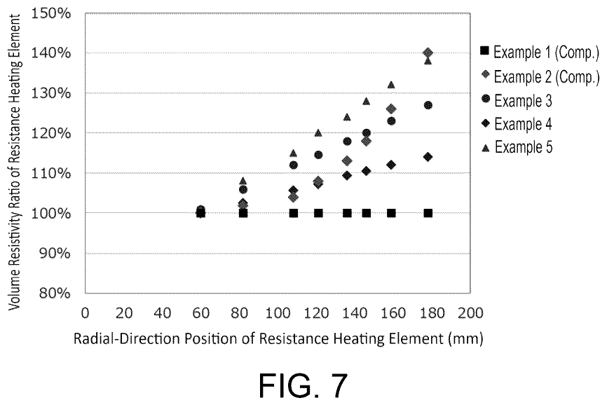

Regarding the resistance heating elements constituting the inner zone control heater circuit 14a and the outer zone control heater circuit 14b embedded in the two-zone ceramic heater, volume resistivities at various positions from the center of the ceramic plate 12 in the radial direction were measured in the following manner. A relative value (%) of the volume resistivity at each of the positions to the volume resistivity (defined as 100%) at a position of 60 mm (outer edge of center portion) from the center of the ceramic plate 12 was determined to examine distribution of the volume resistivity ratio. Results were as illustrated in FIG. 7.

### (Measurement of Volume Resistivity)

In a manner similar to the above-described (1), a ceramic heater for measuring a volume resistivity of a resistance heating element was fabricated, was cut and divided equally into six specimens each having a fan-like planar shape. A terminal having a diameter of 2 mm was attached to a cross-section of each of the resistance heating elements exposed on a cross-section of each of the specimens, and resistance values of the resistance heating elements were measured by a tester of a four-terminal method at a room temperature. A length of each of the arc-shaped resistance heating elements was determined from a radius at each measurement position, and the volume resistivity of each of the resistance heating elements was calculated from the measured resistance value, the length of the resistance heating element, and a cross-sectional area of the resistance heating element (calculated from line diameter of 0.5 mm). In the ceramic heater in Examples, the inner zone control heater circuit 14a and the outer zone control heater circuit 14b were present in two layers at the same radial-direction position. Therefore, two volume resistivities were obtained at each radial-direction position. In such a manner, 12 (=6 pieces×2 layers) volume resistivities based on the six specimens were obtained at each radial-direction position, and an average value thereof was calculated to obtain the volume resistivity at each radial-direction position of the ceramic heater.

### <Resistance Value>

The resistance value of the inner zone control heater circuit 14a and the resistance value of the outer zone control heater circuit 14b were measured at evaluation temperatures of a room temperature and 650° C. The resistance value of the inner zone control heater circuit 14a at the room temperature was measured by connecting the tester of the four-terminal method to the pair of first power supply terminals 18. Likewise, the resistance value of the outer zone control heater circuit 14b at the room temperature was measured by connecting the tester of the four-terminal method to the pair of second power supply terminals 20. The resistance value of the inner zone control heater circuit 14a at 650° C. was calculated from a current value and a voltage value applied to the inner zone control heater circuit 14a. Likewise, the resistance value of the outer zone control heater circuit 14b at 650° C. was calculated from a current value and a voltage value applied to the outer zone control heater circuit 14b. Results were as illustrated in Table 1.

### <Heat Uniformity>

The two-zone ceramic heater 10 was placed in a chamber of a film formation apparatus. The chamber was evacuated, N₂ gas was introduced into the chamber, and N₂ gas pressure inside the chamber was set to 5 Torr. Power was supplied to the inner zone control heater circuit 14a and the outer zone control heater circuit 14b through the first power supply terminals 18 and the second power supply terminals 20, to heat the two-zone ceramic heater 10 to a set temperature of 650° C. At the set temperature, temperature distribution on the first surface 12a of the ceramic plate 12 was measured by an infrared camera. Based on an obtained temperature distribution map, a difference between the highest temperature and the lowest temperature in a plane (namely, in-plane maximum temperature difference) was determined as an index of heat uniformity, and was evaluated based on the following criteria:
Evaluation A: in-plane maximum temperature difference was less than 5.0° C.
Evaluation B: in-plane maximum temperature difference was 5.0° C. or more and 7.0° C. or less
Evaluation C: in-plane maximum temperature difference was 7.0° C. or more Results were as illustrated in Table 1.

### <Total Current Value and Current Value Reduction Effect>

In a manner similar to the above-described heat uniformity, power was supplied from a power supply (power supply voltage: 208 V) to the inner zone control heater circuit 14a and the outer zone control heater circuit 14b through the first power supply terminals 18 and the second power supply terminals 20, to heat the two-zone ceramic heater 10 to a set temperature of 650° C. At this time, values of currents flowing through the inner zone control heater circuit 14a and the outer zone control heater circuit 14b were measured, and the measured current values are added to calculate a total current value. Results were as illustrated in Table 1. Further, the total current value in Example 1 (comparative example) was used as a reference value, and a reduction amount of the total current value in each of Examples 2 to 5 relative to the reference value was illustrated as a reduction effect of the total current value in Table 1.

TABLE 1

| | | Example | Example | Example | Example | Example |
|---|---|---|---|---|---|---|
| | | 1* | 2* | 3 | 4 | 5 |
| Firing | Highest temperature (° C.) | 1760 | 1870 | 1850 | 1840 | 1840 |
| condition | Holding time at highest | 5 | 13 | 8 | 8 | 10 |
| | temperature (hr) | | | | | |
| | Number of times of changing | 2 | 2 | 6 | 4 | 7 |
| | temperature rise rate before | | | | | |
| | highest temperature | | | | | |
| | Range of temperature rise rate | 40 to 60° C./min** | | | | |
| | Firing pressure (kg/cm²) | 60 | 70 | 120 | 120 | 120 |
| Evaluation | Resistance value of inner zone | 2.8 | 2.9 | 3.0 | 2.9 | 3.1 |
| result | control heater circuit at room | | | | | |
| | temperature (Ω) | | | | | |
| | Resistance value of outer zone | 2.7 | 3.5 | 3.3 | 2.9 | 3.6 |
| | control heater circuit at room | | | | | |
| | temperature (Ω) | | | | | |
| | Resistance value of inner zone | 10.3 | 10.6 | 11.4 | 10.7 | 11.8 |
| | control heater circuit at 650° C. | | | | | |
| | (Ω) | | | | | |
| | Resistance value of outer zone | 9.9 | 12.9 | 12.1 | 10.8 | 13.2 |
| | control heater circuit at 650° C. | | | | | |
| | (Ω) | | | | | |
| | Heat uniformity: In-plane | 5.8 | 7.1 | 2.7 | 3.9 | 6.9 |
| | maximum temperature difference | (B) | (C) | (A) | (A) | (B) |
| | (° C.) | | | | | |
| | (Heat uniformity evaluation in | | | | | |
| | brackets) | | | | | |
| | Total current value (A) | 28.4 | 26.3 | 26.2 | 27.4 | 25.5 |
| | (Power supply voltage: 208 V) | | | | | |
| | Current value reduction effect (A) | — | −2.1 | −2.2 | −1.0 | −2.9 |

*indicates comparative example.
**Range of temperature rise rate is temperature range including individual temperature rise rate at plurality of temperature rise stages.

From the distribution of the volume resistivity ratio in the radial direction of the ceramic plate 12 illustrated in FIG. 7, the followings were found about each example.

Example 1 (comparative example) was an example equivalent to the existing technique, and the volume resistivity ratio in the resistance heating element was constant. This meant that there was a limit to increase the resistance value. In Example 2 (comparative example), the volume resistivity ratio was increased toward the outer periphery by improvement of the firing method. However, the volume resistivity ratio was rapidly increased only in a vicinity of the outer periphery. Thus, the profile of the volume resistivity ratio was not desirable. As a result, the heat uniformity was evaluated as C, which was inferior.

In contrast, Example 3 was an example adopting an optimum firing condition, and the desirable volume resistivity profile having a linear gradient in which the volume resistivity ratio was increased toward the outer periphery was achieved. In addition, the outer zone control heater circuit 14b could realize an increase in volume resistivity of 22% relative to the volume resistivity at a position of 60 mm (outer edge of center portion) from the center of the ceramic plate 12. Example 4 showed the profile in which the volume resistivity ratio was increased toward the outer periphery, but the volume resistivity ratio was less than the volume resistivity ratio in Example 3. In this example, the current value reduction effect of about 1 A and excellent heat uniformity (evaluation A) were achieved. Example 5 had the highest volume resistivity among the examples showing the profile having the linear gradient in which the volume resistivity ratio was increased toward the outer periphery. The example showed acceptable heat uniformity (evaluation B), and the current value reduction effect was as high as about 3 A.

The volume resistivity profiles in Examples 1 to 5 were mainly caused by difference in firing condition illustrated in Table 1. Therefore, in the related art, it was necessary to adopt a method of inhibiting heat uniformity such as reduction in heating element line diameter that increases the resistance value and increase in heating density (i.e. packing of a large number of resistance heating elements in same area); however, such a factor for inhibiting the heat uniformity was avoidable by the method according to the present disclosure. As a result, it was possible to achieve the desirable profile in which the volume resistivity of the resistance heating element was linearly increased toward the outer periphery, and to reduce the in-plane temperature difference to about 3° C. (Example 3) at minimum (i.e. heat uniformity was improved). In addition, the total current value was reduced by about 3A (Example 5) at maximum. This is equivalent to 18A in a system including a heater of six times.

What is claimed is:

1. A ceramic heater, comprising:
a ceramic plate having a disc shape, including a first surface on which a wafer is to be placed and a second surface opposite to the first surface, and including, in a planar view, a center portion defined as a circular region within a radius of 60 mm from a center of the ceramic plate, an intermediate portion defined as an annular region having a radius of 80 mm to 120 mm from the center, and an outer peripheral portion defined as an annular region having a radius of 130 mm or more from the center; and
a resistance heating element embedded in the center portion, the intermediate portion, and the outer peripheral portion in the ceramic plate, wherein
the resistance heating element is configured such that a volume resistivity of the resistance heating element is gradually increased as a distance from the center of the ceramic plate is increased, and
when the volume resistivity of the resistance heating element at an outer edge of the center portion is 100%, a ratio of the volume resistivity of the resistance heating element in the intermediate portion is within a range of 102% to 120%, and a ratio of the volume resistivity of the resistance heating element in the outer peripheral portion is within a range of 108% to 139%.

2. The ceramic heater according to claim 1, wherein the resistance heating element has at least one form selected from a group consisting of a coil, a linear zigzag structure, a print pattern, a foil, and a mesh.

3. The ceramic heater according to claim 1, wherein
a part of the resistance heating element embedded in the center portion, a part of the resistance heating element embedded in the intermediate portion, and a part of the resistance heating element embedded in the outer peripheral portion are each disposed in a one-stroke form in a planar view, and
the part of the resistance heating element embedded in the center portion, the part of the resistance heating element embedded in the intermediate portion, and the part of the resistance heating element embedded in the outer peripheral portion are made of a same material.

4. The ceramic heater according to claim 3, wherein
the ceramic heater includes at least two resistance heating elements,
one of the resistance heating elements embedded in the center portion, the intermediate portion, and the outer peripheral portion forms, as one continuous resistance heating element, an outer zone control heater circuit, and
another of the resistance heating elements embedded at a depth position different from a depth position of the outer zone control heater circuit in the center portion, the intermediate portion, and the outer peripheral portion forms, as one continuous resistance heating element, an inner zone control heater circuit independent of the outer zone control heater circuit.

5. The ceramic heater according to claim 3, wherein
the ceramic heater includes at least two resistance heating elements,
the resistance heating element embedded in the outer peripheral portion or in the outer peripheral portion and the intermediate portion forms, as one continuous resistance heating element, an outer zone control heater circuit, and
the resistance heating element embedded in the center portion or in the center portion and the intermediate portion forms, as one continuous resistance heating element, an inner zone control heater circuit independent of the outer zone control heater circuit.

6. The ceramic heater according to claim 1, wherein the ceramic plate contains aluminum nitride or aluminum oxide.

7. The ceramic heater according to claim 6, wherein the ceramic plate contains aluminum nitride and includes an upper ceramic plate providing the first surface and a lower ceramic plate providing the second surface, and aluminum nitride constituting the upper ceramic plate has a volume resistivity exceeding 1.0×10⁸ Ω·cm at 550° C.

8. The ceramic heater according to claim 1, further comprising an inner electrode as an RF electrode and/or an ESC electrode in the ceramic plate.

9. The ceramic heater according to claim 1, further comprising a cylindrical ceramic shaft that is concentrically attached to the second surface of the ceramic plate and includes an internal space.
